(19) United States
(12) Patent Application Publication
(10) Pub. No.: US 2024/0392437 A1
(43) Pub. Date: Nov. 28, 2024

(54) VAPOR DEPOSITION APPARATUS AND SUBSTRATE TREATMENT METHOD

(71) Applicant: ADVANCED MICRO-FABRICATION EQUIPMENT INC. CHINA, Shanghai (CN)

(72) Inventors: Can XU, Shanghai (CN); Yuejun GONG, Shanghai (CN); Yufeng ZHUANG, Shanghai (CN); Shuliang LV, Shanghai (CN); Wei DONG, Shanghai (CN); Zhongshuai XIE, Shanghai (CN); Yuan LI, Shanghai (CN)

(21) Appl. No.: 18/670,589

(22) Filed: May 21, 2024

(30) Foreign Application Priority Data
May 23, 2023 (CN) 202310581853.8
May 23, 2023 (CN) 202310582413.4

(51) Int. Cl. C23C 16/455; C23C 16/44; C23C 16/458; C23C 16/54

(52) U.S. Cl. CPC C23C 16/45544; C23C 16/4408; C23C 16/4412; C23C 16/45565; C23C 16/458; C23C 16/54

(57) ABSTRACT

Vapor deposition apparatus includes: reaction chamber; base including a central area and peripheral area, and capable of moving between high position and low position; shower head at the top of the chamber and configured to introduce plurality of gases; first pumping channel, surrounding the reaction space and formed between the peripheral area of the base assembly and the lower surface of the shower head when the base assembly is located at the high position; and second pumping channel, surrounding the first pumping channel, where the conductance of the second pumping channel is greater than that of the first pumping channel, so that gases are emitted after being subjected to two-stage choke of the first pumping channel and the second pumping channel; and when the base assembly is located at the low position, the fabrication gases are emitted after being subjected to one-stage choke of the second pumping channel.

### CROSS-REFERENCE TO RELATED APPLICATIONS

The present application claims priority to and the benefit of Chinese Patent Application No. 202310581853.8, filed on May 23, 2023, and Chinese Patent Application No. 202310582413.4, filed on May 23, 2023, the disclosures of which are hereby incorporated by reference in their entireties.

### TECHNICAL FIELD

The present application relates to the technical field of semiconductor devices, and in particular to a vapor deposition apparatus and a substrate treatment method.

### BACKGROUND

A large amount of micromachining is required in the manufacturing process of semiconductor devices. The common method is to treat a substrate by adopting an atomic layer deposition process (ALD) or a chemical vapor deposition process (CVD) or a plasma treatment process and using the principle of the reaction chamber. With the characteristic dimensions of the semiconductor devices increasingly reducing and the integration degree of the devices increasingly increasing, the atomic layer deposition process and the chemical vapor deposition process are used more and more widely. For example, in some cases, a surface of a wafer is subjected to thin film deposition treatment by the atomic layer deposition process. The atomic layer deposition process is a chemical vapor thin film deposition technology based on sequentially and surface self-saturation reaction. Substances can be plated on the surface of the substrate layer by layer in the form of a monatomic film, a plurality of process gases are introduced into the reaction chamber through alternating pulse, and a gas-solid phase chemical adsorption reaction occurs on the surface of the substrate to form the thin film. In the atomic deposition process, the chemical reaction of the new layer of atomic film is directly associated with the previous layer, so that one layer of atoms is deposited at each reaction.

Vapor deposition apparatuses have been upgraded many times and their performance has been greatly improved, but there are still many deficiencies in the uniformity of thin film deposition, especially with an increasing dimension of a substrate, existing vapor deposition apparatuses have been difficult to meet uniformity requirements of the thin film. In the thin film deposition process, a plurality of process conditions, such as a gas pumping conductance control condition, will affect the deposition uniformity of the thin film on the surface of the substrate. Improving the gas pumping conductance can improve the cleaning efficiency, but will lead to the uneven distribution of the process gases in the reaction chamber, so that the thickness of the thin film deposited on the surface of the substrate is uneven, and the production yield of the substrate is reduced. reducing the gas pumping conductance can make the process gases be distributed more uniformly, but will reduce the cleaning efficiency.

### SUMMARY

An objective of the present application is to provide a vapor deposition apparatus and a substrate treatment process, so that the gas pumping conductance can be changed, and the gas distribution and cleaning efficiency can be balanced.

To achieve the above objective, the present application is implemented by the following technical solutions:

a vapor deposition apparatus includes:

a reaction chamber, configured to perform a vapor deposition process;

a base assembly, arranged at the bottom of the reaction chamber and including a central area for carrying a substrate and a peripheral area surrounding the central area, the base assembly being capable of moving between a high position and a low position;

a shower head, arranged opposite to the base assembly and at the top of the reaction chamber and configured to introduce a plurality of fabrication gases, a reaction space being formed between a lower surface of the shower head and an upper surface of the central area of the base assembly;

a first pumping channel, surrounding the reaction space and formed between the peripheral area of the base assembly and the lower surface of the shower head when the base assembly is located at the high position;

a second pumping channel, surrounding the first pumping channel, where the conductance of the second pumping channel is greater than that of the first pumping channel, so that the fabrication gases are emitted after being subjected to two-stage choke of the first pumping channel and the second pumping channel; and

when the base assembly is located at the low position, the fabrication gases are emitted after being subjected to one-stage choke of the second pumping channel.

Optionally, the air pressure in the reaction space when the base assembly is located at the high position is higher than the air pressure in the reaction space when the base assembly is located at the low position.

Optionally, the high position and the low position respectively correspond to at least one height value, and the minimum height value of the high position is greater than the maximum height value of the low position.

Optionally, the base assembly can be descended to a substrate transfer position; and the height of the upper surface of the base assembly at the low position is greater than the height of the upper surface of the base assembly at the substrate transfer position, and less than the height of a lower edge of the second pumping channel.

Optionally, the fabrication gases include a process gas and a purge gas; when the base assembly moves to the high position, the process gas enters the reaction space from the shower head, and gas in the reaction space passes through the first pumping channel and is emitted from the second pumping channel; and when the base assembly moves to the low position, the purge gas enters the reaction space from the shower head, and gas in the reaction space is emitted from the second pumping channel.

Optionally, the base assembly includes an edge ring located at the peripheral area of the base assembly; and the first pumping channel is composed of a gap between an upper surface of the edgel ring and a lower surface of the peripheral area of the shower head.

Optionally, the lower surface of the peripheral area of the shower head is lower than a lower surface of the central area of the shower head.

Optionally, an annular boss is arranged on the lower surface of the peripheral area of the shower head.

Optionally, the upper surface of the edge ring is higher than the upper surface of the central area of the base assembly.

Optionally, the edgel ring includes a first cover ring and a second cover ring arranged on an upper surface of the first cover ring.

Optionally, the inner diameter of the first cover ring is less than the outer diameter of the substrate; a substrate transfer opening is formed in a side wall of the reaction chamber; and when the base assembly is descended to the substrate transfer position, the upper surface of the central area of the base assembly is lower than a horizontal plane where the substrate transfer opening is located, and a lower surface of the first cover ring is higher than the horizontal plane where the substrate transfer opening is located.

Optionally, a pumping ring is arranged on a side wall of the reaction chamber; the pumping ring includes an annular gas pumping space; the second pumping channel includes a gas inlet of the annular gas pumping space; the fabrication gases in the reaction space are capable of entering the annular gas pumping space from the gas inlet of the annular gas pumping space; and a gas outlet of the annular gas pumping space communicates with an external gas pumping apparatus.

Optionally, the gas inlet of the annular gas pumping space includes a plurality of holes uniformly or non-uniformly distributed in a circumferential direction of an inner side wall of the pumping ring.

Optionally, the diameter of each of the holes is greater than 4 mm.

Optionally, the number of the holes is greater than 60.

Optionally, the radial width of the first pumping channel is greater than or equal to 30 mm.

Optionally, a distance between an upper surface and a lower surface of the first pumping channel is less than or equal to 2 mm.

Optionally, the vapor deposition apparatus further includes:

a first process gas source, a second process gas source and a purge gas source, where the first process gas source, the second process gas source and the purge gas source communicate with the shower head through a gas conveying pipeline and are configured to respectively convey a first process gas, a second process gas and a purge gas; and

a controller, configured to: move the base assembly to the high position to make the first process gas enter the reaction space to perform a first step, move the base assembly to the low position to make the purge gas enter the reaction space to perform a second step, and move the base assembly to the high position to make the second process gas enter the reaction space to perform a third step.

Optionally, the high position is applied to the deposition of a thin film; and the low position is applied to the cleaning and purging of the reaction space.

A substrate treatment process, applied to the vapor deposition apparatus according to any one of the above, includes the following steps:

controlling a base assembly to move to a high position, introducing, by a shower head, a first process gas to a reaction space, performing chemical adsorption treatment on a substrate on the base assembly, and enabling gas in the reaction space to pass through a first pumping channel and be emitted from a second pumping channel;

controlling the base assembly to move to a low position, introducing, by the shower head, a purge gas to the reaction space for purging, and emitting gas in the reaction space by the second pumping channel; and

controlling the base assembly to move to the high position, introducing, by the shower head, a second process gas to the reaction space, performing chemical reaction treatment on the substrate on the base assembly, and enabling the gas in the reaction space to pass through the first pumping channel and be emitted from the second pumping channel;

controlling the base assembly to move to a low position, introducing, by the shower head, a purge gas to the reaction space for purging, and emitting gas in the reaction space by the second pumping channel; and

repeating the above steps until a thin film deposited on a surface of the substrate meets requirements.

Optionally, the substrate treatment method further includes the following steps:

controlling the base assembly to descend to a substrate transfer position, transferring the substrate to be treated to a reaction chamber, or transferring the treated substrate out of the reaction chamber.

Compared with the prior art, the present application has at least one of the following advantages:

by adoption of the vapor deposition apparatus provided by the present application, when the base assembly moves to the high position, the reaction chamber has two stages of pumping channels, the first stage is a first pumping channel, the second stage is a second pumping channel, and the conductance of the second pumping channel is greater than that of the first pumping channel; since the first pumping channel is adjacent to the reaction space and the conductance is small, so that the reaction space has a relatively small gas pumping flux, the rapid and even distribution of the process gases in the reaction space is facilitated, and the surface of the substrate has higher thin film uniformity; and when the base assembly moves to the low position, a distance between the upper surface of the peripheral area of the substrate and the lower surface of the shower head is large, and the outflow of the gas in the reaction space is not basically affected, so the first pumping channel disappears or is ignored, the reaction space is only subjected to gas pumping by the second pumping channel, a large gas pumping flux is achieved, the rapid emission of the gas is facilitated, and the cleaning efficiency of the purge gas is improved.

### BRIEF DESCRIPTION OF THE DRAWINGS

To describe the technical solution of the present application more clearly, the accompanying drawings required in the description are introduced simply below. Apparently, the accompanying drawings described below are one embodiment of the present application. For those of ordinary skill in the art, other drawings can be obtained according to the accompanying drawings without creative effort.

FIG. 1 is a sectional structure diagram of a vapor deposition apparatus at a high position according to an embodiment of the present application;

FIG. 2 is a sectional structure diagram of a vapor deposition apparatus at a low position according to an embodiment of the present application;

FIG. 3 is a sectional structure diagram of a vapor deposition apparatus at a substrate transfer position according to an embodiment of the present application;

FIG. 4 is a sectional structure diagram of another vapor deposition apparatus at a high position according to an embodiment of the present application;

FIG. 5a, FIG. 5b and FIG. 5c are sectional structure diagrams of a vapor deposition apparatus at a high position, a low position and a substrate transfer position according to another embodiment of the present application; and

FIG. 6 is a flowchart of a substrate treatment method according to an embodiment of the present application.

### DETAILED DESCRIPTION

The solution proposed by the present application will be further described below in detail with reference to the accompanying drawings and the specific embodiments. The advantages and features of the present application will become clearer from the following description. It should be noted that the drawings are in a very simplified form and all use imprecise scales, which are only used to conveniently and clearly assist in describing the objective of the embodiments of the present application. To make the objects, features and advantages of the present application more comprehensible, please refer to the accompanying drawings. It should be noted that the structures, proportions, sizes and the like shown in the drawings attached to this specification are only used to match the content disclosed in the specification, for those who are familiar with this technology to understand and read, and are not used to limit the limiting condition of implementation of the present application, so it has no technical substantive meaning, and any modification of structure, change of proportional relationship or adjustment of size shall still fall within the scope covered by the disclosed technical content of the present application without affecting the effect and purpose of the present application.

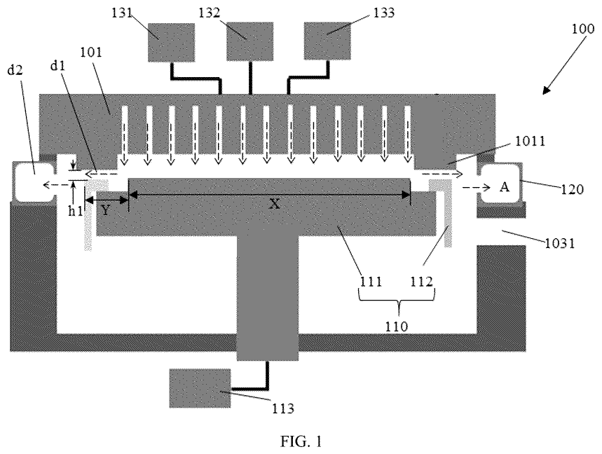

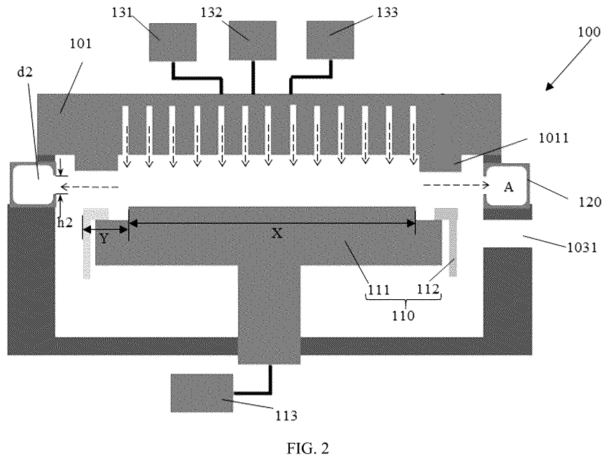

In the process treatment process of thin film deposition, the gas pumping conductance of the process condition is very important. Based on this, as shown in FIG. 1 and FIG. 2, this embodiment provides a vapor deposition apparatus, including a reaction chamber 100 configured to perform a vapor deposition process; a base assembly 110 capable of moving up and down is arranged at the bottom of the reaction chamber 100; an upper surface of the base assembly 110 is formed by a central area X for carrying a substrate (not shown in the figure) and a peripheral area Y surrounding the central area X; and one or more substrates can be placed on an upper surface of the central area X. A shower head 101 is arranged at the top of the reaction chamber 100 and configured to introduce a plurality of fabrication gases to treat the substrate. The base assembly 110 and the shower head 101 are arranged oppositely; a reaction space is formed between a lower surface of the shower head 101 and the upper surface of the central area X of the base assembly 110; and the plurality of fabrication gases can be alternately introduced into the reaction space by the shower head 101. According to the requirement of the reaction in a certain technological process, when the types of the fabrication gases change, the height of the upper surface of the base assembly 110 can be switched between the high position and the low position, so that the size of the reaction space and the size of a gas outlet of the reaction space can be changed; and when the base assembly 110 moves to the high position, a first pumping channel d1 surrounding the reaction space is formed between the upper surface of the peripheral area Y and the lower surface of the shower head 101.

Specifically, when the fabrication gases change, a distance between the upper surface of the peripheral area Y of the base assembly 110 and the lower surface of the shower head 101 can be changed, so that the outflow speed of the fabrication gases in the reaction space can be changed, and the tendency between the uniformly and the exhaust efficiency can be adjusted according to actual requirements. It can be understood that when the base assembly 110 moves to the high position, the upper surface of the peripheral area Y is closer to the lower surface of the shower head 101, thereby producing resistance to the gas emission in the reaction space. Therefore, the first pumping channel d1 is formed between the upper surface of the peripheral area Y and the lower surface of the shower head 101, that is, conductance will be produced when the fabrication gases are emitted from the first pumping channel d1. The vapor deposition apparatus further has a second pumping channel d2 surrounding the first pumping channel d1, and the hole diameter of the second pumping channel d2 cooperates with the gas pumping pressure, so that conductance will also be generated when the fabrication gases pass through the second pumping channel d2. The conductance of the second pumping channel d2 is greater than that of the first pumping channel d1, so that the fabrication gases are emitted after being subjected to two-stage choke of the first pumping channel d1 and the second pumping channel d2.

It can be seen from FIG. 1 and FIG. 2 that when the base assembly 110 moves to the high position, the reaction chamber 100 has two stages of pumping channels, the first stage is a first pumping channel d1, the second stage is a second pumping channel d2, and the conductance of the second pumping channel d2 is greater than that of the first pumping channel d1; since the first pumping channel d1 is adjacent to the reaction space and the conductance is small, so that the reaction space has a relatively small gas pumping flux, the uniform distribution of the process gases in the reaction space is facilitated, and the surface of the substrate has higher thin film uniformity. When the base assembly 110 moves to the low position, a distance between the upper surface of the peripheral area of the base assembly 110 and the lower surface of the shower head 101 is large, and the outflow of the gas in the reaction space is not basically affected, so the first pumping channel d1 disappears or is ignored, the reaction space is only subjected to gas pumping by the second pumping channel d2, and the fabrication gases are emitted after being subjected to the one-stage choke of the second pumping channel d2, thereby achieving a large gas pumping flux, facilitating the rapid emission of the gas and improving the cleaning efficiency of the purge gas. In some embodiments, when the base assembly 110 moves to the low position, the height of the upper surface of the peripheral area Y of the base assembly 110 is less than that of the second pumping channel d2 (that is, less than the height of a lower edge of a gas inlet of the second pumping channel d2), so that the influence of the shower head 101 and the peripheral area Y of the base assembly 110 on the pumping of the fabrication gases can be reduced.

The fabrication gases include a process gas (such as raw material gas TiCl₄ and reactive gas NH₃) and a purge gas (such as N₂). Based on the vapor deposition apparatus, it can be understood that the high position is applied to the deposition of a thin film; when the base assembly 110 moves to the high position, the flow direction of the process gas in the reaction chamber 100 is shown in the dashed arrow in FIG. 1, the process gas enters the reaction space through the shower head 101 and cannot be emitted from the first pumping channel d1 completely at once, and the retention effect can be generated in the reaction space, so that the gas is distributed more uniformly, and the uniformity of the thin film on the surface of the substrate is improved; in the reaction process, the gas in the reaction space is required to be emitted from the second pumping channel d2 after passing through the first pumping channel d1; the low position is applied to the cleaning and purging of the reaction space; when the base assembly 110 moves to the low position, the flow direction of the purge gas in the reaction chamber 100 is shown in the dashed arrow in FIG. 2, the purge gas enters the reaction space from the shower head 101; at this time, the gas in the reaction space is directly emitted from the second pumping channel d2 with a large gas pumping flux without passing through the first pumping channel d1 with a small gas pumping flux, so that the cleaning efficiency can be improved, cleaning can be rapidly completed, and the subsequent step can be performed; furthermore, the second pumping channel d2 also makes the gas in the reaction space generate a retention effect smaller than that of the first pumping channel d1, so that the fabrication gases in the previous step on the surface of the part in the reaction space can be completely purged, and the cleaning effect is better.

In one embodiment, the vapor deposition apparatus may further include a controller configured to automatically control the base assembly 110 to move up and down and cooperatively control the introduction of the process gas or the purge gas. The base assembly 110 includes a table 111; a central area of the base table 111 is configured to carry a substrate; the base table 111 may be connected to a first lifting driving mechanism 113 such as a motor driver; and the first lifting driving mechanism 113 drives the base assembly 110 to move up and down. When it is necessary to introduce the process gas, the controller controls the first lifting driving mechanism 113 to drive the base assembly 110 to move to the high position, and controls the process gas to be introduced from the shower head 101 to the reaction chamber 100. When it is necessary to introduce the purge gas, the controller controls the first lifting driving mechanism 113 to drive the base assembly 110 to move to the low position, and controls the purge gas to be introduced from the shower head 101 to the reaction chamber 100.

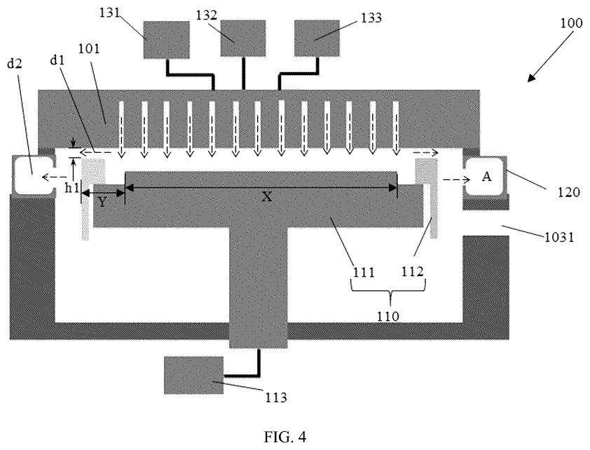

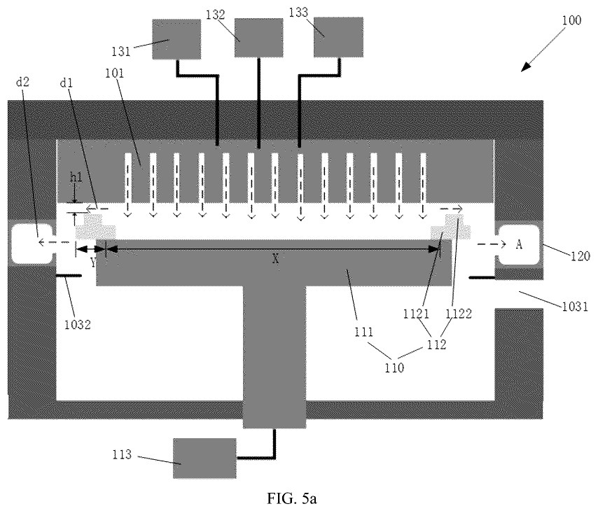

Further, as shown in FIG. 1 and FIG. 4, when the base assembly 110 moves to the high position, the upper and lower surfaces of the first pumping channel d1 have a first distance h1, and the first distance h1 may be less than or equal to 2 mm so as to generate a retention effect in the reaction space. The excessively large distance h1 will cause the fabrication gases to escape from the reaction space, and the effect of uniformly spreading on the surface of the substrate cannot be achieved.

As shown in FIG. 1 and FIG. 4, the base assembly 110 includes an edge ring 112 located at the peripheral area Y of the base assembly 110, and the edge ring 112 is configured to cover the edge of the base table 111 of the base assembly 110, so that deposits generated at the edge of the base table 111 can be avoided, and the maintenance cost of the base table 111 can be reduced. In this embodiment, the first pumping channel d1 is composed of a gap between the upper surface of the edge ring 112 and the lower surface of the peripheral area of the shower head 101, that is, when the base assembly 110 ascends to the high position, the upper surface of the edge ring 112 and the lower surface of the peripheral area of the shower head 101 are close to each other, and the first pumping channel d1 is formed between the two.

To ensure that the reaction space has a sufficient volume to accommodate the fabrication gases, in one embodiment, as shown in FIG. 4, the upper surface of the edge ring 112 is higher than the upper surface of the central area X of the base assembly 110. Therefore, when the base assembly 110 ascends to the high position, a distance between the upper surface of the edge ring 112 and the lower surface of the shower head 101 is small, so that the requirement of the first distance h1 is met. In another embodiment, as shown in FIG. 1, the lower surface of the peripheral area of the shower head 101 is lower than the lower surface of the central area of the shower head 101, that is, an annular boss 1011 is arranged at the lower surface of the peripheral area of the shower head 101. Therefore, when the base assembly 110 ascends to the high position, a distance between the lower surface of the annular boss 1011 of the shower head 101 and the upper surface of the peripheral area Y of the base assembly 110 is small, so that the requirement of the first distance h1 is met.

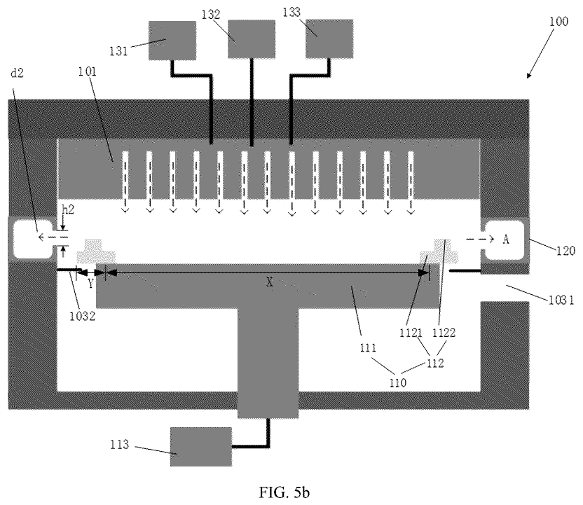

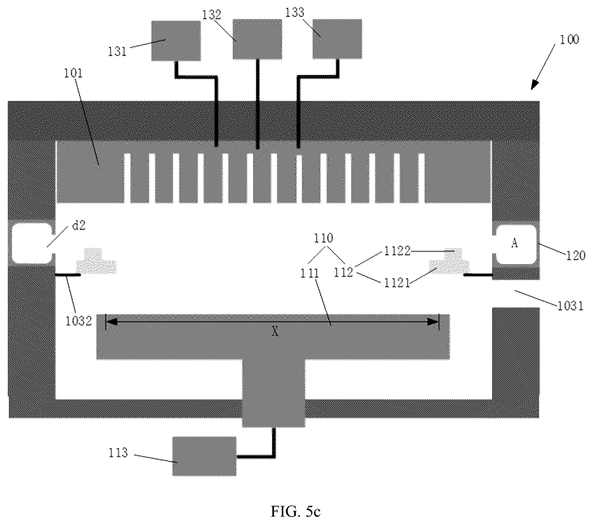

In another vapor deposition apparatus, as shown in FIG. 5a, FIG. 5b and FIG. 5c, the edge ring 112 includes a first cover ring 1121 and a second cover ring 1122 arranged on the upper surface of the first cover ring 1121, thereby facilitating the separated replacement of the two cover rings and maintenance. The inner diameter of the first cover ring 1121 is less than the outer diameter of the substrate, so the first cover ring 1121 can be pressed on the peripheral area of the upper surface of the substrate (not shown in the figure), thereby avoiding the defect such as the warping of the substrate in the treatment process. FIG. 5a and FIG. 5b schematically show the structural diagrams of the first cover ring 1121 pressed on the peripheral area of the upper surface of the substrate when the base assembly 110 is located at the high position and the low position. As shown in FIG. 5a, when the base assembly 110 is located at the high position, a distance between the upper surface of the second cover ring 1122 and the lower surface of the shower head 101 is small, so that the requirement of the first distance h1 is met, and the gap between the second cover ring 1122 and the shower head 101 form the first pumping channel d1.

A substrate transfer opening 1031 is formed on a side wall of the reaction chamber 100. When the base assembly 110 descends to the position of the substrate transfer opening 1031 (that is, the substrate transfer position), as shown in FIG. 5c, the central area X of the base assembly 110 is lower than a horizontal plane where the substrate transfer opening 1031 is located, and the lower surface of the first cover ring 1121 is higher than the horizontal plane where the substrate transfer opening 1031 is located. Optionally, a cover ring supporting piece 1032 is arranged at the position above the substrate transfer opening 1031 on the side wall of the reaction chamber 100; in the descending process of the base assembly 110, the edge ring 112 is supported by the cover ring supporting piece 1032, the base table 111 of the base assembly 110 continuously descends to the position of the substrate transfer opening 1031, the substrate to be treated is transferred to the reaction chamber 100 and is placed on the upper surface of the base table 111; and in the ascending process of the base table 111, the edge ring 112 may be pressed on the peripheral area of the upper surface of the substrate and continuously ascends accordingly.

Further, the radial width of the first pumping channel d1 may be greater than or equal to 30 mm. It may be understood that in a case that the longitudinal height of the first pumping channel d1 is small and in cooperation with the large radial width, the “narrow and long” first pumping channel d1 is formed, so that the retention effect formed by the reaction space is stronger, thereby further improving the uniformity of the thin film on the surface of the substrate.

It can be seen from the above that the vapor deposition apparatus in this embodiment enables the base assembly 110 to be located at the high position when the process gas is introduced, so that the upper surface of the peripheral area Y of the base assembly 110 and the lower surface of the shower head 101 are close to each other to form the first pumping channel d1, the gas pumping flux of the first pumping channel d1 is small, and the uniformity of the thin film on the surface of the substrate can be improved better. Therefore, the second pumping channel d2 in this embodiment may be designed to have the gas pumping flux larger than that of the existing vapor deposition apparatus. For example, as shown in FIG. 2 and FIG. 5b, the upper and lower surfaces of the second pumping channel d2 have a second distance h2, and the second distance h2 is greater than or equal to 4 mm.

In this embodiment, a pumping ring 120 is further arranged on the side wall of the reaction chamber 100, and is configured to emit the gas inside the reaction chamber 100, that is, the reaction waste product, out of the reaction chamber 100. As shown in FIG. 1, the pumping ring 120 is arranged between the shower head 101 and the side wall of the reaction chamber 100, and has an annular gas pumping space A; the second pumping channel d2 includes a gas inlet of the annular gas pumping space A; the fabrication gases in the reaction space can enter the annular gas pumping space A from the gas inlet of the annular gas pumping space A; and the gas outlet of the annular gas pumping space A communicates with an external gas pumping apparatus. It may be understood that the conductance of the annular gas pumping space A mainly depends on the conductance of the gas inlet. Therefore, the external gas pumping apparatus may pump the fabrication gases in the reaction space to the annular gas pumping space A through the second pumping channel d2, and emit the gas out of the chamber from the gas outlet. Optionally, the gas inlet of the annular gas pumping space A includes a plurality of holes distributed uniformly along the circumferential direction of the inner side wall of the pumping ring 120, for example, the number of the holes is greater than 60, and the diameter of each of the holes is greater than or equal to 4 mm. Therefore, the gas distribution uniformity can be maintained in the gas pumping process, and gas can be pumped rapidly and uniformly. In some embodiments, a plurality of holes distributed non-uniformly may further be arranged in a circumferential direction of the inner side wall of the pumping ring 120 to adjust the gas flow.

The shower head 101 is connected to an external gas source, and is configured to uniformly inject the process gas or the purge gas into the reaction chamber 100 from the gas source and perform a thin film deposition process or purging at the treatment area above the substrate, thereby ensuring that the thin film deposition process can be performed normally. The gas source includes a first process gas source 131, a second process gas source 132 and a purge gas source 133. The first process gas source 131, the second process gas source 132 and the purge gas source 133 communicate with the shower head 101 through a gas conveying pipeline. The gas conveying pipeline may be a plurality of discrete pipelines for respectively conveying the first process gas, the second process gas and the purge gas into the shower head, or may be a multi-channel manifold for mixing the first process gas, the second process gas and the purge gas and then conveying the mixture into the shower head. In this embodiment, the shower head 101 is connected to the first process gas source 131 through a first gas conveying pipeline, is connected to the second process gas source 132 through a second gas conveying pipeline, and is connected to the purge gas source 133 through a third gas conveying pipeline, thereby respectively conveying the fabrication gases including the first process gas, the second process gas and the purge gas into the reaction space. The controller of the vapor deposition apparatus in this embodiment is configured to switch the height position of the base assembly 110 when the fabrication gases change, for example: move the base assembly 110 to the high position to make the first process gas enter the reaction space to perform a first step, move the base assembly 110 to the low position to make the purge gas enter the reaction space to perform a second step, and move the base assembly 110 to the high position to make the second process gas enter the reaction space to perform a third step.

In some other embodiments, the high position may at least include one height value, the low position may further at least include one height value, and the minimum height value of the high position is greater than the maximum height value of the low position. That is, the position of the base assembly 110 may be changed every time being switched to the high position as long as it is sufficient to form the first pumping channel d1, so the appropriate retention time can be formed correspondingly according to different process gases. Similarly, the position of the base assembly 110 may be changed every time being switched to the low position as long as no resistance to the gas emission of the reaction space is generated.

Specifically, a first inflation valve and a first gas conveying valve are respectively arranged at the positions where the first gas conveying pipeline is connected to the first process gas source 131 and the shower head 101; a second inflation valve and a second gas conveying valve are respectively arranged at the positions where the second gas conveying pipeline is connected to the second process gas source 132 and the shower head 101; and a third inflation valve and a third gas conveying valve are respectively arranged at the positions where the third gas conveying pipeline is connected to the purge gas source 133 and the shower head 101. The controller is configured to: control the base assembly 110 to move to the high position, and control the first inflation valve and the first gas conveying valve to start, so that the first process gas enters the reaction space to perform a first step; after the first step is performed, control the first inflation valve and the first gas conveying valve to close, control the base assembly 110 to move to the low position, and control the third inflation valve and the third inflation valve to open, so that the purge gas enters the reaction space to perform a second step; and after the second step is performed, control the third inflation valve and the third gas conveying valve to close, control the base assembly 110 to move to the high position, and control the second inflation valve and the second gas conveying valve to open, so that the second process gas enters the reaction space to perform a third step. Optionally, when the first process gas is introduced to perform the first step and the purge gas is introduced to perform the second step, the second inflation valve can be controlled to open and the second gas conveying valve can be controlled to close, so that the second process gas is inflated in the second gas conveying pipeline. Therefore, when the second process gas is introduced to perform the third step and after the second gas conveying valve is controlled to open, the flow rate of the second process gas introduced in the reaction space is large, thereby facilitating the formation of a better retention effect in the reaction space and improving the uniformity of the thin film on the surface of the substrate.

It can be understood that the volume of the reaction space when the base assembly 110 is located at the high position is less than the volume of the reaction space when the base assembly 110 is located at the low position, so that the gas pressure in the reaction space when the base assembly 110 is located at the high position is higher than the gas pressure in the reaction space when the base assembly 110 is located at the low position. Therefore, the gas can be rapidly diffused in the reaction space when the base assembly 110 is located at the high position, thereby improving the gas distribution uniformity; and the gas pumping choke when the base assembly 110 is located at the low position is small, thereby facilitating the rapid emission of the gas. Therefore, in the technical solution of this embodiment, the high position and low position of the base assembly 110 can be switched in different steps of the same process, and the high position and low position can be switched as required in different processes. For example, the base assembly 110 may be arranged at a higher position when the process performed in the reaction chamber requires high gas distribution uniformity, and the base assembly 110 may be arranged at a lower position when the process performed in the reaction chamber requires high replacement rate of the gas.

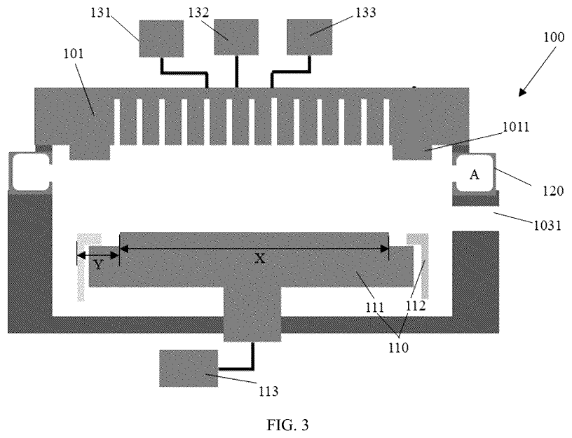

As mentioned above, after the substrate is treated, the base assembly 110 may also descend to the substrate transfer position, as shown in FIG. 3 and FIG. 5c, the substrate transfer position corresponds to the position of the substrate transfer opening 1031 formed on the side wall, so that the treated substrate can be transferred out of the reaction chamber 100 through the substrate transfer opening 1031, and the substrate to be treated can be transferred. Based on this, the height of the upper surface when the base assembly 110 is at the low position may be set greater than that of the upper surface when the base assembly is at the substrate transfer position, that is, as shown in FIG. 2, FIG. 3, FIG. 5b and FIG. 5c, the low position is higher than the substrate transfer position. Therefore, after the base assembly 110 at the high position performs the first step or the third step, it is unnecessary to descend the base assembly 110 to the lower substrate transfer position, but the base assembly 110 is descended to the low position located between the high position and the substrate transfer position, so that the purge gas can be introduced to perform the step of cleaning the reaction chamber 100, thereby improving the substrate treatment efficiency of the reaction chamber 100.

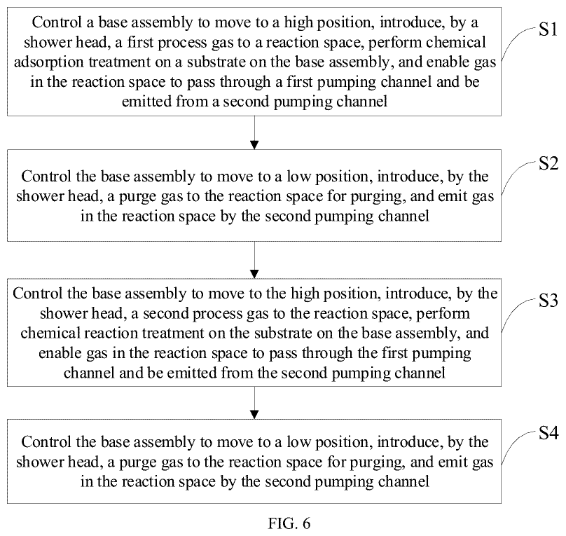

Based on the same inventive concept, this embodiment further provides a substrate treatment method, implemented by the vapor deposition apparatus. As shown in FIG. 6, the method includes the following steps:

S1: a base assembly is controlled to move to a high position, a first process gas is introduced to a reaction space by a shower head, chemical adsorption treatment is performed on a substrate on the base assembly, and gas in the reaction space passes through a first pumping channel and is emitted from a second pumping channel.

Due to the arrangement of the first pumping channel, the reaction space is compressed and reduced, the first process gas can rapidly fill the reaction space, and the first process gas can uniformly fill the reaction space in seconds or less than one second, so that the substrate at each area in the reaction space can be treated uniformly.

S2: the base assembly is controlled to move to a low position, a purge gas is introduced by the shower head to the reaction space for purging, and gas in the reaction space is emitted from the second pumping channel.

Therefore, the reaction space is stretched and expanded, the first pumping channel loses the effect of blocking the gas flow due to the expanded edge of the reaction space, and the purge gas in the reaction space can utilize the flow rate advantage of the second pumping channel to evacuate the purge gas and the process gas in the previous step most rapidly, thereby achieving the cleanliness meeting the process requirement. Purging can be completed in seconds by moving the base assembly to the low position, thereby meeting the clean requirement. In some embodiments, the purging process can be completed in a time range of less than 1 second.

S3: the base assembly is controlled to move to the high position, a second process gas is introduced by the shower head to the reaction space, chemical reaction treatment is performed on the substrate on the base assembly, and gas in the reaction space passes through the first pumping channel and is emitted from the second pumping channel.

Therefore, the reaction space is compressed to an appropriate size again, so that the second process gas can rapidly fill the reaction space. Furthermore, through the two-stage pumping channels, the second process gas can stay in the reaction space for sufficient time and can be distributed in each area of the reaction space maximally and uniformly, and the gas concentration and distribution participating the second step of the reaction can rapidly meet the process requirement.

S4: the base assembly is controlled to move to a low position, a purge gas is introduced by the shower head to the reaction space for purging, and gas in the reaction space is emitted from the second pumping channel.

The above steps S1 to S4 are repeated until the thin film deposited on the surface of the substrate meets the requirement.

In addition, the substrate treatment process further includes the steps: the base assembly is controlled to descend to a substrate transfer position, the substrate to be treated is transferred to a reaction chamber, or the treated substrate is transferred out of the reaction chamber.

The base assembly in this embodiment may be switched among the high position, the low position and the substrate transfer position. When the base assembly is located at the high position, a thin film growth process gas is introduced into the reaction chamber. Due to the arrangement of the first pumping channel, the size of the reaction space is reduced, and the thin film process gas can fill the whole reaction space rapidly and uniformly, so that each area of the substrate can be treated uniformly. When the base assembly is located at the low position, the purge gas is introduced into the reaction chamber. Since the position of the base assembly is descended, a distance between the lower surface of the shower head and the peripheral area of the base assembly becomes larger, thereby not forming more obstacles to the purge gas. The second pumping channel has a large conductance, and the purge gas can be rapidly emitted out of the reaction chamber after rapidly cleaning the previous thin film growth process gas. Since the vapor deposition apparatus is required to perform cyclic switching in seconds between the introduction of the thin film growth process gas and the purge gas. According to the technical solution disclosed in this embodiment, the thin film growth process gas can rapidly fill the reaction space, the uniformity of the substrate can be improved, and the emission time of the purge gas can be shortened, thereby greatly improving the manufacturing process efficiency. After the substrate is treated, the base assembly continuously descends to the substrate transfer position, so that the substrate can be taken and placed.

It should be noted that in this specification, relational terms such as the first and second are only used to distinguish one entity or operation from another entity or operations, and do not necessarily require or imply that there is any such actual relationship or order between these entities or operations. Furthermore, the term “comprises”, “includes” or any other variant thereof are intended to cover non-exclusive inclusion, so that a process, method, object or device including a series of elements not only includes those elements, but also includes other elements not explicitly listed, or also includes elements inherent to such process, method, object or device. Without further limitations, an element defined by the phrase “comprising a . . . ” does not exclude the presence of additional identical elements in the process, method, object or device including the element.

Although the content of the present application has been described in detail through the aforementioned preferred embodiments, it should be recognized that the above description should not be considered as limiting the present application. Various modifications and alternatives to the present application will become apparent to those skilled in the art upon reading the foregoing disclosure. Accordingly, the protection scope of the present application shall be limited by the appended claims.

What is claimed is:

1. A vapor deposition apparatus, comprising:
a reaction chamber, configured to perform a vapor deposition process;
a base assembly, arranged at the bottom of the reaction chamber and comprising a central area for carrying a substrate and a peripheral area surrounding the central area, the base assembly being capable of moving between a high position and a low position;
a shower head, arranged opposite to the base assembly and at the top of the reaction chamber and configured to introduce a plurality of fabrication gases, a reaction space being formed between a lower surface of the shower head and an upper surface of the central area of the base assembly;
a first pumping channel, surrounding the reaction space and formed between the peripheral area of the base assembly and the lower surface of the shower head when the base assembly is located at the high position; and
a second pumping channel, surrounding the first pumping channel, wherein the conductance of the second pumping channel is greater than that of the first pumping channel, so that the fabrication gases are emitted after being subjected to two-stage choke of the first pumping channel and the second pumping channel; and
when the base assembly is located at the low position, the fabrication gases are emitted after being subjected to one-stage choke of the second pumping channel.

2. The vapor deposition apparatus according to claim 1, wherein the air pressure in the reaction space when the base assembly is located at the high position is higher than the air pressure in the reaction space when the base assembly is located at the low position.

3. The vapor deposition apparatus according to claim 1, wherein the high position and the low position respectively correspond to at least one height value, and the minimum height value of the high position is greater than the maximum height value of the low position.

4. The vapor deposition apparatus according to claim 1, wherein the base assembly is capable of being descended to a substrate transfer position; and the height of an upper surface of the base assembly at the low position is greater than the height of the upper surface of the base assembly at the substrate transfer position, and less than the height of a lower edge of the second pumping channel.

5. The vapor deposition apparatus according to claim 1, wherein the fabrication gases comprise a process gas and a purge gas; when the base assembly moves to the high position, the process gas enters the reaction space from the shower head, and the gas in the reaction space passes through the first pumping channel and is emitted from the second pumping channel; and when the base assembly moves to the low position, the purge gas enters the reaction space from the shower head, and the gas in the reaction space is emitted from the second pumping channel.

6. The vapor deposition apparatus according to claim 1, wherein the base assembly comprises an edge ring located at the peripheral area of the base assembly; and the first pumping channel is composed of a gap between an upper surface of the edge ring and a lower surface of a peripheral area of the shower head.

7. The vapor deposition apparatus according to claim 6, wherein the lower surface of the peripheral area of the shower head is lower than a lower surface of a central area of the shower head

8. The vapor deposition apparatus according to claim 7, wherein an annular boss is arranged on the lower surface of the peripheral area of the shower head.

9. The vapor deposition apparatus according to claim 6, wherein the upper surface of the edge ring is higher than the upper surface of the central area of the base assembly.

10. The vapor deposition apparatus according to claim 9, wherein the edge ring comprises a first cover ring and a second cover ring arranged on an upper surface of the first cover ring.

11. The vapor deposition apparatus according to claim 10, wherein the inner diameter of the first cover ring is less than the outer diameter of the substrate; a substrate transfer opening is formed in a side wall of the reaction chamber; and when the base assembly is descended to the substrate transfer position, the upper surface of the central area of the base assembly is lower than a horizontal plane where the substrate transfer opening is located, and a lower surface of the first cover ring is higher than the horizontal plane where the substrate transfer opening is located.

12. The vapor deposition apparatus according to claim 1, wherein a pumping ring is arranged on a side wall of the reaction chamber; the pumping ring comprises an annular gas pumping space; the second pumping channel comprises a gas inlet of the annular gas pumping space; the fabrication gases in the reaction space are capable of entering the annular gas pumping space from the gas inlet of the annular gas pumping space; and a gas outlet of the annular gas pumping space communicates with an external gas pumping apparatus.

13. The vapor deposition apparatus according to claim 12, wherein the gas inlet of the annular gas pumping space comprises a plurality of holes uniformly or non-uniformly distributed in a circumferential direction of an inner side wall of the pumping ring.

14. The vapor deposition apparatus according to claim 13, wherein the diameter of each of the holes is greater than 4 mm.

15. The vapor deposition apparatus according to claim 13, wherein the number of the holes is greater than 60.

16. The vapor deposition apparatus according to claim 1, wherein the radial width of the first pumping channel is greater than or equal to 30 mm.

17. The vapor deposition apparatus according to claim 1, wherein a distance between an upper surface and a lower surface of the first pumping channel is less than or equal to 2 mm.

18. The vapor deposition apparatus according to claim 1, further comprising:
a first process gas source, a second process gas source and a purge gas source, wherein the first process gas source, the second process gas source and the purge gas source communicate with the shower head through a gas conveying pipeline and are configured to respectively convey a first process gas, a second process gas and a purge gas; and
a controller, configured to: move the base assembly to the high position to make the first process gas enter the reaction space to perform a first step, move the base assembly to the low position to make the purge gas enter the reaction space to perform a second step, and move the base assembly to the high position to make the second process gas enter the reaction space to perform a third step.

19. The vapor deposition apparatus according to claim 1, wherein the high position is applied to the deposition of a thin film; and the low position is applied to the cleaning and purging of the reaction space.

20. A substrate treatment method, applied to the vapor deposition apparatus according to claim 1, and comprising the following steps:
controlling the base assembly to move to the high position, introducing, by the shower head, the first process gas to the reaction space, performing chemical adsorption treatment on a substrate on the base assembly, and enabling the gas in the reaction space to pass through the first pumping channel and be emitted from the second pumping channel;
controlling the base assembly to move to the low position, introducing, by the shower head, the purge gas to the reaction space for purging, and emitting the gas in the reaction space from the second pumping channel;
controlling the base assembly to move to the high position, introducing, by the shower head, a second process gas to the reaction space, performing chemical reaction treatment on the substrate on the base assembly, and enabling the gas in the reaction space to pass through the first pumping channel and be emitted from the second pumping channel;
controlling the base assembly to move to the low position, introducing, by the shower head, the purge gas to the reaction space for purging, and emitting the gas in the reaction space from the second pumping channel; and
repeating the above steps until a thin film deposited on a surface of the substrate meets requirements.

21. The substrate treatment method according to claim 20, further comprising the following steps:
controlling the base assembly to descend to a substrate transfer position, transferring the substrate to be treated into the reaction chamber, or transferring the treated substrate out of the reaction chamber.
